(19) United States
(12) Patent Application Publication
(10) Pub. No.: US 2008/0173859 A1
(43) Pub. Date: Jul. 24, 2008

(54) Storage node and methods of forming the same, phase change memory device having a storage node and methods of fabricating and operating the same

(75) Inventors: Ji-hyun Hur, Yongin-si (KR); Yoon-ho Khang, Yongin-si (KR); Hyo-sug Lee, Suwon-si (KR); Hyuk-soon Choi, Seongnam-si (KR); Jai-kwang Shin, Anyang-si (KR); Jae-joon Oh, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/000,716

(22) Filed: Dec. 17, 2007

(30) Foreign Application Priority Data
Dec. 27, 2006 (KR) 10-2006-0135545

(51) Int. Cl. H01L 47/00

(52) U.S. Cl. 257/3; 438/482; 257/E47.005; 257/E47.001

(57) ABSTRACT

A storage node, phase change memory device having a storage node, a method of fabricating the phase change memory device and a method of operating the phase change memory device are provided. The phase change memory device includes a switching device and a storage node connecting to the switching device. The storage node includes a bottom electrode, a phase change layer formed on the bottom electrode, a material layer formed on the phase change layer and a top electrode formed on the phase change layer around the material layer.

### PRIORITY STATEMENT

This application claims the benefit of priority under 35 U.S.C. §119 from Korean Patent Application No. 10-2006-0135545, filed on Dec. 27, 2006, in the Korean Intellectual Property Office, the contents of which are incorporated herein by reference in its entirety.

### BACKGROUND

1. Field

Example embodiments relate to a storage node. Other example embodiments relate to a phase change memory device having a storage node and methods of fabricating and operating the same.

2. Description of the Related Art

A phase change memory device may include a storage node having a phase change material layer and a transistor connected to the storage node.

FIG. 1 is a diagram illustrating a structure of a storage node connected to a transistor (not shown) in a conventional phase change memory device.

Referring to FIG. 1, the storage node in the conventional phase change memory device includes a bottom electrode 12 surrounded by a first insulating interlayer 10, a bottom electrode contact layer 16 formed on the bottom electrode 12 and surrounded by a second insulating interlayer 14. A phase change layer 18 and a top electrode 20 may be sequentially formed on the second insulating interlayer 14.

In operating a conventional phase change memory device having the storage node of FIG. 1, if a reset current (I) is applied to the phase change layer 18, the reset current (I) flows from the bottom electrode contact layer 16 to the top electrode 20. A portion A1 of the phase change layer 18, which contacts the bottom electrode contact layer 16, may be changed to an amorphous state by the reset current (I). If the portion A1 that contacts the bottom electrode contact layer 16 is changed to the amorphous state, the electric current flowing through the phase change layer 18, which is measured in a read operation, may be smaller than a reference current. After applying the reset current (I), the state of the amorphous portion A1 may change to the original crystalline state by applying a set current to the phase change layer 18. The set current may be weaker than the reset current (I). If the set current is applied to the phase change layer 18 and the portion A1 is changed to the crystalline state, the electric current flowing through the phase change layer 18 that is measured in the read operation may be larger than the reference current.

As described above, the currents measured in the read operation when the portion A1 of the phase change layer 18 is in the amorphous state and in the crystalline state, respectively, may be different from each other. Data 1 or 0 may be recorded on the phase change layer 18 using the difference of the measured currents. If 1 is recorded on the phase change layer 18, the portion A1 in the phase change layer 18 may be in the amorphous state. If 0 is recorded on the phase change layer 18, the portion A1 of the phase change layer 18 may be in the crystalline state. The material states corresponding to the data 1 and 0 may be reversed.

In the conventional phase change memory device, the top electrode 20 may be disposed (or formed) on an entire upper surface of the phase change layer 18. If the reset current (I) is applied to the phase change layer 18, the reset current (I) flows through the shortest path connecting the bottom electrode contact layer 16 and the top electrode 20. The reset current (I) proceeds in a direction perpendicular to the bottom electrode contact layer 16 to the top electrode 20 as denoted by the arrows of FIG. 1.

If the reset current (I) is applied, the portion A1 of the phase change layer 18 that contacts the bottom electrode contact layer 16 may be changed to the amorphous state mainly due to the Joule heat generated by the reset current (I). Because resistance increases when the path through which the reset current (I) flows increases, the Joule heat generated from the path also increases. Because the path of the reset current (I) increases under the same applied voltage, the reset current (I) may be reduced.

In the conventional phase change memory device, the reset current (I) flowing through the phase change layer 18 flows upward from the bottom electrode contact layer 16 (i.e., in a direction perpendicular to a lower surface of the phase change layer 18). The reset current (I) flows through the shortest path connecting the portion of the phase change layer 18 contacting the bottom electrode contact layer 16 to the upper surface of the phase change layer 18. As described above, the path, through which the reset current (I) flows, in the conventional phase change memory device may be the path having the lowest resistance making it difficult to reduce (or decrease) the reset current (I) in the conventional phase change memory device.

### SUMMARY

Example embodiments relate to a storage node. Other example embodiments relate to a phase change memory device having a storage node and methods of fabricating and operating the same.

According to example embodiments, there is provide a storage node including a bottom electrode, a phase change layer formed on the bottom electrode, a material layer formed on the phase change layer and a top electrode formed on the phase change layer around the material layer.

According to example embodiments, there is also provided a phase change memory device including a switching device and the storage node described above. The storage node is connected to the switching device.

According to example embodiments, an electric conductivity of the material layer may be lower than an electric conductivity of the top electrode. The memory device may include a bottom electrode contact layer formed between the bottom electrode and the phase change layer.

A width of the material layer may be substantially equal to, or greater than, a width of the bottom electrode contact layer. The width of the material layer may be smaller than a width of the top electrode. The material layer may be symmetric based on a center of the phase change layer. The material layer may be an insulating layer, or a conductive layer, having a lower electric conductivity than that of the top electrode. The material layer may protrude downward to be surrounded by the phase change layer. The insulating layer may be a silicon oxide layer or a nitride layer.

According to example embodiments, there is provided a method of forming a storage node including forming a phase change layer on a bottom electrode, forming a top electrode on the phase change layer, forming a hole through which the phase change layer is exposed in the top electrode and filling a material layer in the hole.

According to example embodiments, there is provided a method of fabricating a phase change memory device including a switching device and a storage node formed as described above. The storage node may be connected to the switching device.

According to example embodiments, the above methods may include forming a bottom electrode contact layer between the bottom electrode and the phase change layer.

The hole may be symmetrical based on a center of the top electrode. A diameter of the hole may be substantially equal to, or greater than, a width of the bottom electrode contact layer. The diameter of the hole may be smaller than a width of the top electrode.

According to other example embodiments, another method of forming a storage node is provided, the method including forming a phase change layer on a bottom electrode, forming a material layer on a portion of the phase change layer and forming a top electrode on the phase change layer around the material layer.

According to other example embodiments, there is a method of fabricating a phase change memory device having the storage node described above.

According to example embodiments, there is provided a method of operating a phase change memory device including a switching device and a storage node connected to the switching device. The method may include maintaining a turn-on state of the switching device and applying an operating voltage to the storage node. The operating voltage may be one selected from the group including a write voltage, a read voltage and an erase voltage.

### BRIEF DESCRIPTION OF THE DRAWINGS

Example embodiments will be more clearly understood from the following detailed description taken in conjunction with the accompanying drawings. FIGS. 1-15 represent non-limiting, example embodiments as described herein.

FIG. 1 is a diagram illustrating a cross-sectional view of a storage node in a conventional phase change memory device;

FIG. 2 is a diagram illustrating a cross-sectional view of a phase change memory device according to example embodiments;

FIG. 3 is a diagram illustrating a cross-sectional view of a storage node in the phase change memory device of FIG. 2;

FIGS. 4 through 11 are diagrams illustrating cross-sectional views of a method of fabricating the phase change memory device according to example embodiments;

FIG. 12 is a diagram illustrating a plan view of a storage node used in a simulation for testing operational properties of the phase change memory device according to example embodiments;

FIG. 13 is a diagram illustrating a cross-sectional view of the storage node taken along line 13-13′ in FIG. 12;

FIG. 14 is a photograph showing the simulation results of a phase change memory device according to the conventional art; and

FIG. 15 is a photograph showing the simulation results of the phase change memory device according to example embodiments.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to a storage node. Other example embodiments relate to a phase change memory device having a storage node and methods of fabricating and operating the same.

A phase change memory device according to example embodiments will be described.

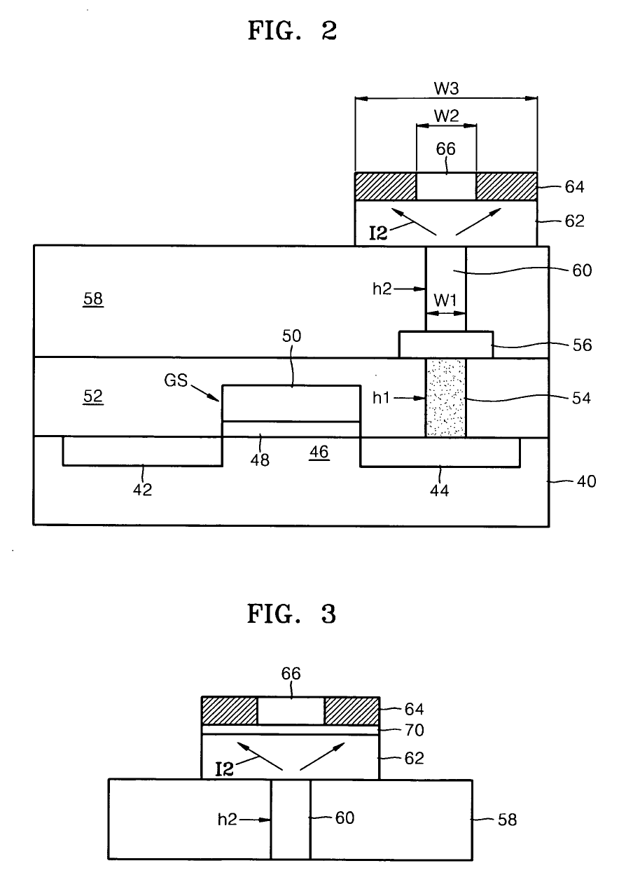

Referring to FIG. 2, a first impurity region 42 and a second impurity region 44 are formed on an active area of a substrate 40. The first and second impurity regions 42 and 44 may be separated from each other by a desired distance. A conductive impurity (e.g., n-type impurity) may be doped in each of the first and second impurity regions 42 and 44. One of the first and second impurity regions 42 and 44 may be a source and the other region may be a drain. A gate stack (GS) may be formed on the substrate 40 between the first and second impurity regions 42 and 44. A channel region 46 may be formed under the gate stack. The gate stack has a structure which may have a gate insulating layer 48 and a gate electrode 50 that are sequentially stacked. The gate stack may include a spacer (not shown) covering side surfaces of the gate insulating layer 48 and the gate electrode 50. The first and second impurity regions 42 and 44, the channel region 46 and the gate stack form a transistor.

A first insulating interlayer 52 may be formed on the substrate so as to cover the transistor. A first contact hole h1, exposing the second impurity region 44, may be formed in the first insulating interlayer 52. The first contact hole h1 may be filled with a conductive plug 54. A bottom electrode 56 that covers an exposed upper surface of the conductive plug 54 may be formed on the first insulating interlayer 52. The bottom electrode 56 may function as a pad layer of a bottom electrode contact layer 60.

A second insulating interlayer 58 that covers the bottom electrode 56 may be formed on the first insulating interlayer 52. A second contact hole h2, exposing a portion of the bottom electrode 56, may be formed in the second insulating interlayer 58. The second contact hole h2 may be filled with a bottom electrode contact layer 60. The bottom electrode 56 and the bottom electrode contact layer 60 form a lower stack (LS) structure of the storage node. The bottom electrode contact layer 60 may be a TiN layer or a TaAlN layer. The second insulating interlayer 56 may be formed of the same material as the first insulating interlayer 52.

A phase change layer 62 covering an exposed upper surface of the bottom electrode contact layer 60 may be formed on the second insulating interlayer 52. The phase change layer 62 may be a GST layer. The phase change layer 62 may be formed of a different phase changing material (e.g., a binary, a trinary, a quaternary chalcogenide and combinations thereof).

An insulating layer 66 may be formed on a desired region of the phase change layer 62. A top electrode 64 may be formed on the phase change layer 62 around the insulating layer 66. The top electrode 64 may be formed of TiN. The insulating layer 66 may be an oxide layer. The oxide layer may be a silicon oxide layer or a different oxide layer from the silicon oxide layer. The insulating layer 66 may be a different type of insulating layer (e.g., a nitride layer).

The insulating layer 66 may be a material layer that has a lower electric conductivity than that of the top electrode 64. The insulating layer 66 may be formed on a portion of the phase change layer 62 corresponding to the bottom electrode contact layer 60. The insulating layer 66 (or the material layer) may be formed symmetrical with respect to a center of the top electrode 64.

A width W2 of the insulating layer 66 may substantially equal to, or greater than, a width W1 of the bottom electrode contact layer 60. The width W2 of the insulating layer 66 may be smaller than an outer diameter W3 of the top electrode 64. The lower stack structure, the phase change layer 62 and the top electrode 64 around the insulating layer 66 may form a storage node for storing data.

The insulating layer 66 may protrude downwards. The insulating layer 66 may be surrounded by the phase change layer 62.

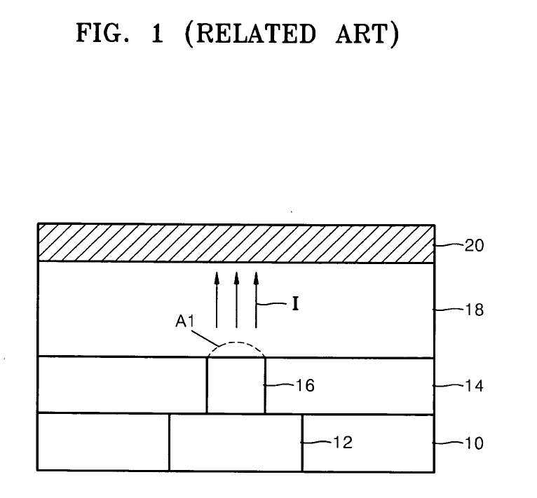

In the storage node having the above structure, a distance between the bottom electrode contact layer 60 and the top electrode 64 may be longer than that of the conventional storage node (refer to FIG. 1) due to the insulating layer 66. As such, a path of electric current I2 passing through the phase change layer 62 between the bottom electrode contact layer 60 and the top electrode 64 may increase. As the path increases, the resistance of the path of the electric current I2 increases.

If an equal operating voltage is applied between the lower electrode contact layer 60 and the upper electrode 64 of a conventional storage node and a storage node according to example embodiments and a reset current I2 flows between the lower electrode contact layer 60 and the upper electrode 64, the reset current I2 may be smaller than that of the conventional storage node. As such, the resistance of the current path increases and the heat generation amount may be substantially similar to that of the conventional storage node.

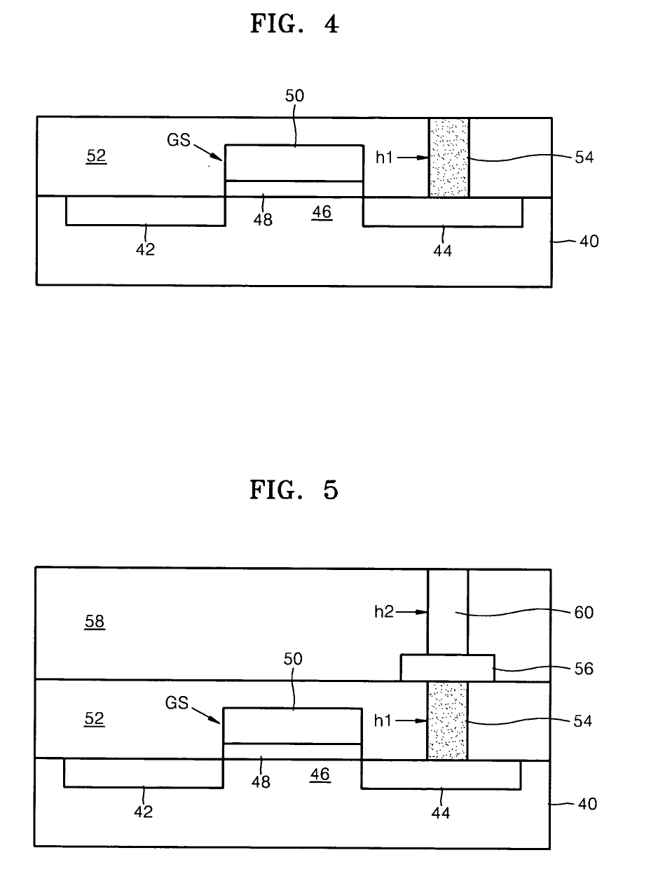

Referring to FIG. 3, an adhesive layer 70 may be formed between the top electrode 64 and the phase change layer 62. The adhesive layer 70 may be a material layer for increasing an adhesive force between the top electrode 64 and the phase change layer 62. The adhesive layer 70 may be a Ti layer. The adhesive layer 70 may be formed between the top electrode 64 and the phase change layer 62. The adhesive layer 70 may extend between the insulating layer 66 and the phase change layer 62.

Although not shown in FIG. 3, a diffusion prevention layer may be formed between the adhesive layer 70 and the phase change layer 62. The diffusion prevention layer may prevent impurities of the stack structure formed on the phase change layer 62 from diffusing to the phase change layer 62.

A method of fabricating the phase change memory device according to example embodiments will be described.

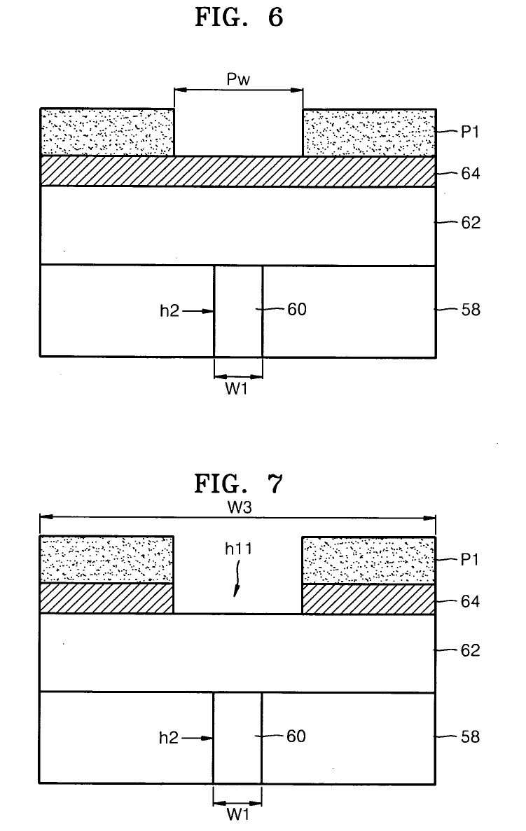

Referring to FIG. 4, a gate stack (GS) may be formed on a portion of an active area on a substrate 40. The gate stack may be formed by sequentially stacking a gate insulating layer 48 and a gate electrode 50. A spacer may be formed on side surfaces of the gate insulating layer 48 and the gate electrode 50. A conductive impurity opposite to that the substrate 40 may be ion-implanted into the active area of the substrate 40 using the gate stack as a mask. First and second impurity regions 42 and 44 may be formed on the substrate 40 with the gate stack interposed. The first impurity region 42, the second impurity region 44 and the gate stack form a transistor. The transistor may be a type of switching device. A region under the gate insulating layer 48 in the substrate 40 may become a channel area 46.

A first insulating interlayer 52 covering the transistor may be formed on the substrate 40. The first insulating interlayer 52 may be formed of a dielectric material (e.g., SiOₓ or SiOₓN_{y}). The first insulating interlayer 52 may be formed using different dielectric material(s). A first contact hole h1, exposing the second impurity region 44, may be formed in the first insulating interlayer 52. A conductive material may be filled in the first contact hole h1 to form a conductive plug 54.

Referring to FIG. 5, a bottom electrode 56 that covers an exposed upper surface of the conductive plug 54 may be formed on the first insulating interlayer 52. The bottom electrode 56 may be a TiN electrode or a TiAlN electrode. The bottom electrode 56 may be a silicide electrode including a metal ion. The metal ion may be one selected from the group including Ag, Au, Al, Cu, Cr, Co, Ni, Ti, Sb, V, Mo, Ta, Nb, Ru, W, Pt, Pd, Zn, Mg and combinations thereof. A second insulating interlayer 58 covering the bottom electrode 56 may be formed on the first insulating interlayer 52. The second insulating interlayer 58 may be formed of the same material as that of the first insulating interlayer 52 or other materials. A second contact hole h2, exposing a portion of an upper surface of the bottom electrode 56, may be formed in the second insulating interlayer 58. The second contact hole h2 may be filled with TiN or TiAlN. A bottom electrode contact layer 60 may be formed contacting a phase change layer.

Stack structures (not shown) may be formed under the second insulating interlayer 58 and the bottom electrode contact layer 60.

Referring to FIG. 6, the phase change layer 62 covering an upper surface of the bottom electrode contact layer 60 may be formed on the second insulating interlayer 58. The phase change layer 62 may be formed as a GST layer. The phase change layer 62 may be formed of any phase changing material known in the art. The phase change layer 62 may be formed of a binary, a ternary, a quaternary chalcogenide and combinations thereof. A top electrode 64 may be formed on the phase change layer 62. A photosensitive pattern P1 exposing a portion of the top electrode 64 may be formed on the top electrode 64. The exposed part of the top electrode 64 may be formed above the bottom electrode contact layer 60. A width Pw of the exposed portion of the top electrode 64 may be substantially equal to, or greater than, a width W1 of the bottom electrode contact layer 60. The exposed part of the top electrode 64 may be etched using the photosensitive pattern P1 as an etching mask. The etching may be performed until the phase change layer 62 is exposed.

Referring to FIG. 7, the exposed portion of the top electrode 64 may be removed to form a hole h11 that exposes the phase change layer 62 in the top electrode 64. A diameter of the hole h11 may be substantially equal to, or greater than, the width W1 of the bottom electrode contact layer 60. The diameter of the hole h11 may be smaller than a width W3 of the top electrode 64.

Referring to FIG. 8, after the etching process, the hole h11 of the phase change layer 62 may be filled with an insulating layer 66. The insulating layer 66 may be an oxide layer or a nitride layer. The oxide layer may be a silicon oxide layer or a different oxide layer from the silicon oxide layer. The insulating layer 66 may be formed using a material having a lower electric conductivity than that of the top electrode 64. The insulating layer 66 may be a conductive layer having a lower electric conductivity than that of the top electrode 64. The insulating layer 66 may be formed on the photosensitive pattern P1. After forming the insulating layer 66, the photosensitive pattern P1 and the insulating layer formed on the photosensitive pattern P1 may be removed using a lift-off method.

Referring to FIG. 9, the insulating layer 66 on the exposed area of the phase change layer 62 remains. The insulating layer 66 covering the exposed portion of the phase change layer 62 may be thicker than the top electrode 64. After removing the photosensitive pattern P1, an upper surface of the insulating layer 66 may be polished until a height of the insulating layer 66 becomes equal, or substantially equal, to that of the top electrode 64. The polishing may be performed using a polishing method known in the art (e.g., a chemical mechanical polishing (CMP)).

Referring to FIG. 10, after the polishing process, a photosensitive pattern P2 that covers the insulating layer 66 may be formed on the top electrode 64. A portion of the top electrode 64, which will be included in the storage node, may be delimited (or established) by the photosensitive pattern P2.

Referring to FIG. 11, the top electrode 64 and the phase change layer 62 around the photosensitive pattern P2 may be sequentially etched using the photosensitive pattern P2 as an etching mask. The etching may be performed until the second insulating interlayer 58 is exposed. The photosensitive pattern P2 may be removed. Reference symbol S represents a storage node.

A method of operating the phase memory device according to example embodiments will be described. The phase memory device of FIG. 2 will be used as an example.

The insulating layer 66 may be formed on the phase change layer 62 at a position corresponding to the hole h11. The top electrode 64 may be formed on the phase change layer around the insulating layer 66.

A voltage higher than a threshold voltage may be applied to the gate electrode 50 to turn on the transistor. An operating voltage may be applied between the top electrode 64 and the bottom electrode 56. The operating voltage may be a voltage for applying the reset current (i.e., a write voltage). The operating voltage may be a voltage for applying a set current (i.e., an erase voltage). The operating voltage may be a voltage for applying the current between the reset current and the set current (i.e., a read voltage).

If the operating voltage is the read voltage, the current flowing through the phase change layer 62 may be measured. The measured current may be compared with a reference current. If the measured current is lower than the reference current, the portion of the phase change layer 62 contacting the bottom electrode contact layer 60 may be in the amorphous state and data 1 is recorded in the phase change memory device. If the measured current is higher than the reference current, there is no amorphous region in the phase change layer 62 and data 0 is recorded in the phase change memory device. The determination of the data 1 or 0 recorded in the phase change memory device may be performed using the reverse method as described above.

Next, a simulation test performed on a conventional phase change memory device and a phase change memory device according to example embodiments and the corresponding results will be described.

The simulation test identified the reset current and the temperature distribution of the phase change layer 62 when the top electrode 64 was formed on a diagonal direction from the bottom electrode contact layer 60.

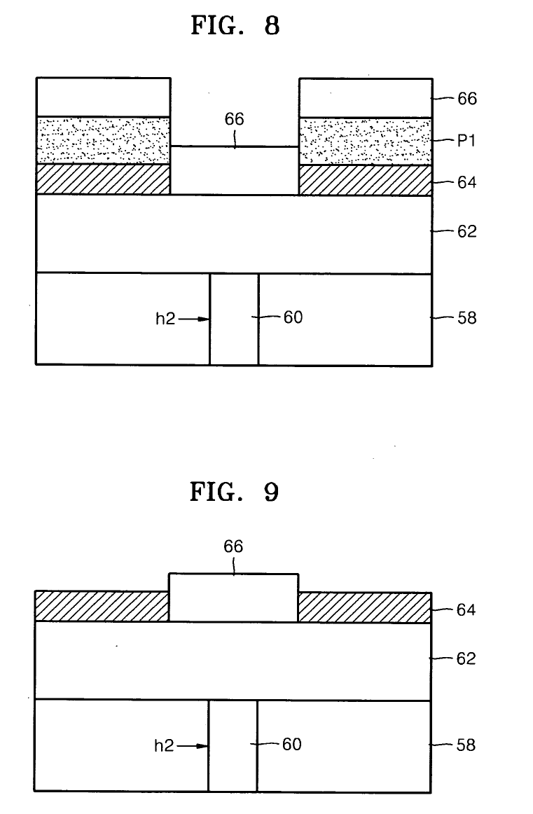

In the following simulation, the phase change memory device having the structure of FIG. 12 was used and a conventional phase change memory device having the storage node structure of FIG. 1 was used as a comparative example.

FIG. 12 is a diagram illustrating a plan view of a storage node in a phase change memory device according to example embodiments.

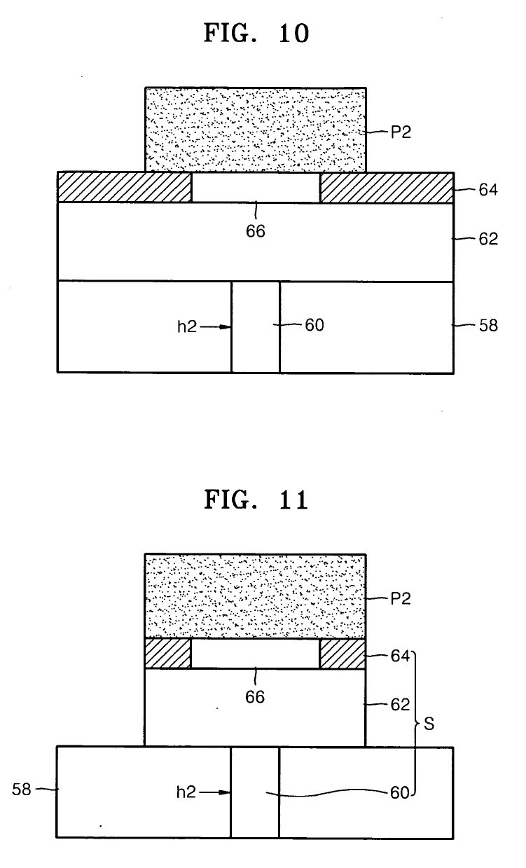

In FIG. 13, the storage node of FIG. 12 is taken along line 13-13′. The cross-section of the storage node is positioned such that the top electrode 64 faces the right side and the upper portion of the cross-section is shown. If the storage node of FIG. 13 is viewed from the arrow direction, the storage node appears as shown in FIG. 12. In FIG. 12, the bottom electrode contact layer 60 is shown for reference.

Referring to FIGS. 12 and 13, the phase change layer 62 may be cylindrical. The top electrode 64 may be formed as a ring. The insulating layer 66 may be formed like a disc having the same, or substantially the same, thickness as the top electrode 64 in the storage node of the phase change memory device. The comparative storage node had a similar structure.

In the phase change memory device according to example embodiments, the phase change layer 62 may be a GST layer, the bottom electrode contact layer 60 may be a TiAlN layer, the insulating layer 66 may be a SiO₂ layer and the top electrode 64 may be a TiAlN layer. The inner diameter of the top electrode 64 (e.g., the diameter of the insulating layer 66 (W2)) may be 150 nm. The diameter of the phase change layer 62 (W3) may be 250 nm and the diameter of the bottom electrode contact layer 60 may be 50 nm.

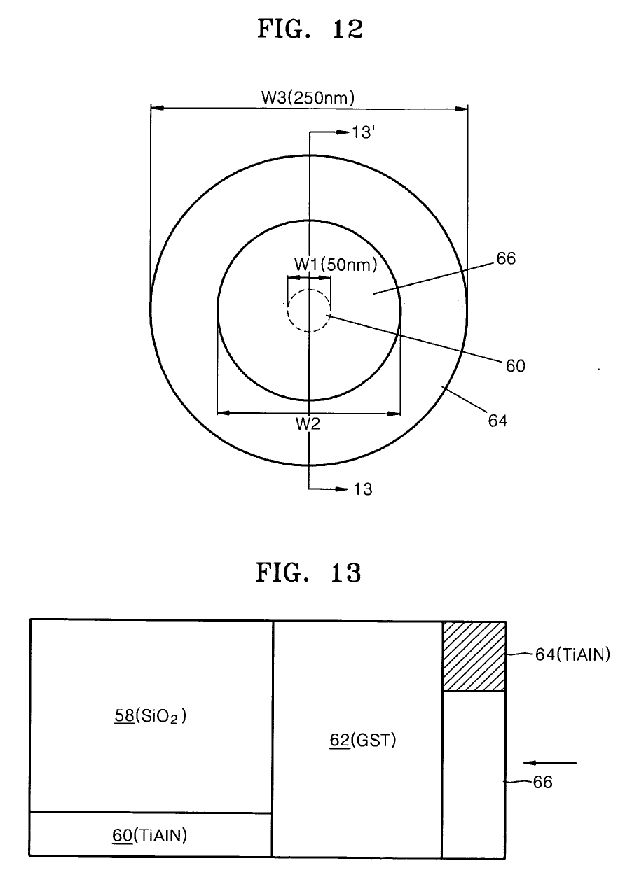

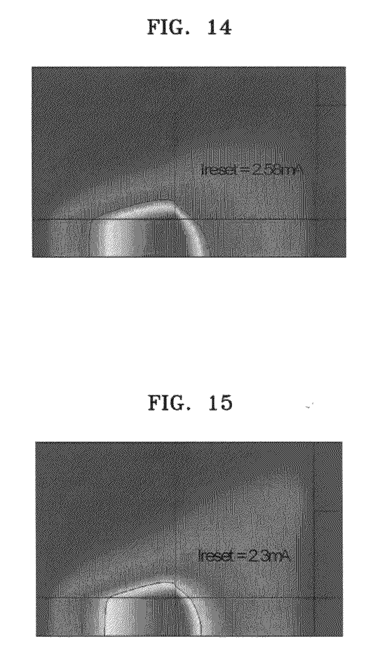

In FIGS. 14 and 15, the same voltage was applied to the phase change memory device according to example embodiments and to the comparative phase change memory device such that the reset current flowing through the phase change layer. The reset current flowing through the phase change layer was measured. The temperature distribution of the phase change layer, when the reset current was flowing, was measured.

FIG. 14 is a photograph showing the simulation results of a phase change memory device according to the conventional art. FIG. 15 is a photograph showing the simulation results of the phase change memory device according to example embodiments.

Referring to FIG. 14 and FIG. 15, if the reset current was applied, the temperature of the region of the phase change layer, which contacts the bottom electrode contact layer, increased such that the region changed to an amorphous state.

The reset current of the comparative phase change memory device was 2.58 mA. The reset current of the phase change memory device according to example embodiments was 2.3 mA. The reset current of the present phase change memory device according to example embodiments was lower than that of the comparative phase change memory device.

The top electrode in the storage node of the phase change memory device according to example embodiments is located diagonally from the bottom electrode contact layer. The top electrode and the bottom electrode contact layer are not located on the same, or substantially the same, vertical line. The distance between the top electrode and the bottom electrode contact layer becomes longer than that if the top electrode and the bottom electrode contact layer are located on the same vertical line. The path, through which the current passes through the phase change layer is formed between the top electrode and the bottom electrode contact layer, increases.

As described above, because the current path passing through the phase change layer in the phase change memory device increases, the resistance of the path increases. The same operating voltage may be applied to the phase change memory device according to example embodiments and the conventional phase change memory device, however the reset current supplied to the phase change layer according to example embodiments is lower than that of the conventional phase change memory device.

In the phase change memory device according to example embodiments, the reset current may be lowered and the integrity of the phase change memory device may increase. Because the insulating layer is formed above the bottom electrode contact layer, the transfer of undesired heat to the program region of the phase change layer (e.g., the amorphous region contacting the bottom electrode contact layer) may be activated. As such, the properties of the program region may not change unexpectedly.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

1. A storage node, comprising:
a phase change layer on a bottom electrode;
a material layer on the phase change layer; and
a top electrode on the phase change layer around the material layer.

2. A phase change memory device, comprising:
a switching device; and
the storage node according to claim 1 connected to the switching device.

3. The phase change memory device of claim 2, wherein an electric conductivity of the material layer is lower than an electric conductivity of the top electrode.

4. The phase change memory device of claim 2, further comprising a bottom electrode contact layer between the bottom electrode and the phase change layer.

5. The phase change memory device of claim 4, wherein a width of the material layer is equal to or greater than a width of the bottom electrode contact layer, and the width of the material layer is smaller than a width of the top electrode.

6. The phase change memory device of claim 5, wherein the material layer is symmetrical based on a center of the phase change layer.

7. The phase change memory device of claim 2, wherein the material layer is an insulating layer or a conductive layer having a lower electric conductivity than that of the top electrode.

8. The phase change memory device of claim 7, wherein the insulating layer is a silicon oxide layer or a nitride layer.

9. The phase change memory device of claim 2, wherein the material layer protrudes downward and is surrounded by the phase change layer.

10. The phase change memory device of claim 9, wherein the material layer is an insulating layer or a conductive layer having a lower electric conductivity than that of the top electrode.

11. A method of operating the phase change memory device according to claim 2, comprising:
maintaining a turn-on state of the switching device; and
applying an operating voltage to the storage node.

12. The method of claim 11, wherein the operating voltage is one selected from the group including a write voltage, a read voltage and an erase voltage.

13. A method of forming a storage node, comprising:
forming a phase change layer on a bottom electrode;
forming a top electrode on the phase change layer;
exposing the phase change layer through a hole formed in the top electrode; and
filling a material layer in the hole.

14. A method of fabricating a phase change memory device, comprising:
forming a switching device; and
connecting the storage node formed according to claim 13 to the switching device.

15. The method of claim 14, wherein the hole is symmetrical based on a center of the top electrode.

16. The method of claim 14, wherein the material layer is an insulating layer or a conductive layer having an electric conductivity lower than that of the top electrode.

17. The method of claim 16, wherein the insulating layer is a silicon oxide layer or a nitride layer.

18. The method of claim 14, further comprising:
forming a bottom electrode contact layer between the bottom electrode and the phase change layer.

19. The method of claim 18, wherein a diameter of the hole is equal to or greater than a width of the bottom electrode contact layer, and the diameter of the hole is smaller than a width of the top electrode.

20. A method of forming a storage node, comprising:
forming a phase change layer on a bottom electrode;
forming a material layer on a portion of the phase change layer; and
forming a top electrode on the phase change layer around the material layer.

21. A method of fabricating a phase change memory device, comprising:
forming a switching device; and
connecting the storage node formed according to claim 20 to the switching device.

22. The method of claim 21, wherein the material layer is symmetrical based on a center of the top electrode.

23. The method of claim 21, wherein the material layer is an insulating layer or a conductive layer having an electric conductivity lower than that of the top electrode.
